(19) United States
(12) Patent Application Publication
(10) Pub. No.: US 2011/0011737 A1
(43) Pub. Date: Jan. 20, 2011

(54) HIGH-POWER PULSE MAGNETRON SPUTTERING APPARATUS AND SURFACE TREATMENT APPARATUS USING THE SAME

(75) Inventors: Jin-Yu Wu, Taoyuan County (TW); Wen-Lung Liung, Taoyuan County (TW); Ming-Jui Tsai, Taoyuan County (TW); Der-Jun Jan, Taoyuan County (TW); Cheng-Chang Hsieh, Taoyuan County (TW); Shin-Wu Wei, Taoyuan County (TW); Chia-Cheng Lee, Taoyuan County (TW); Chi-Fong Ai, Taoyuan County (TW)

Correspondence Address: WPAT, PC;INTELLECTUAL PROPERTY ATTORNEYS, 7225 BEVERLY ST., ANNANDALE, VA, 22003, US

(73) Assignee: Institute of Nuclear Energy Research Atomic Energy Council, Executive Yuan, Taoyuan County (TW)

(21) Appl. No.: 12/505,042

(22) Filed: Jul. 17, 2009

(51) Int. Cl. C23C 14/35

(52) U.S. Cl. 204/298.16

(57) ABSTRACT

A magnetron sputtering apparatus suitable for coating on a workpiece is provided. The magnetron sputtering apparatus includes a vacuum chamber, a holder, a magnetron plasma source and a high-power pulse power supply set, wherein the magnetron plasma source includes a base, a magnetron controller and a target. A reactive gas is inputted into the vacuum chamber, and the holder supporting the workpiece is disposed inside the vacuum chamber. The magnetron plasma source is disposed opposite to the workpiece, wherein the magnetron controller is disposed in the base, and the target is disposed on the base. The high-power pulse power supply set is coupled to the vacuum chamber, the magnetron plasma source and the holder, and a high voltage pulse power is inputted to the magnetron plasma source to generate plasma to coat a film on the surface of the workpiece.

### FIELD OF THE INVENTION

The present invention relates to a magnetron sputtering apparatus and surface treatment apparatus using the same, and more particularly, to a high-power pulse magnetron sputtering apparatus and its relating surface treatment apparatus.

### BACKGROUND OF THE INVENTION

Generally, there are two types of plasma coating techniques usually used in industry, which are arc plasma coating and magnetron sputtering coating. For the technique of arc plasma coating, it is usually performed in a vacuum environment of about 10⁻³ torr for producing plasma between a cathode electrode and an anode electrode by means of a low-voltage discharge of about tens of volt, by that a target placed on the cathode electrode can be ionized into plasma and thus deposited upon a workpiece. It is noted that when a large current is used for producing arc, it can result the plasma to have a high degree of ionization. Hence, the arc plasma coating is advantageous in its good coating adhesion to the workpiece surface.

However, as a portion of the target is subjected to a high temperature caused by the arc of the said arc plasma coating and is melted, the melting target will release microparticles of size ranged between 1 μm to 10 μm that is also going to deposit on the workpiece surface. Consequently, the surface roughness of the workpiece is increased and thus the coating quality is decreased. Although there are already many prior-art methods for filtering out those microparticles existed in the plasma of the arc plasma coating process by increasing the amount of curved magnetic channels, despite of such methods will cause the deposition rate to decrease, it still can not prevent the workpiece from being contaminated by certain micron-scaled microparticles as they can travel passing such curved magnetic channels and reach the workpiece surface, causing adverse affect in relation to the coating quality.

For the magnetron sputtering coating, it is characterized in its ability of depositing a delicate film, and thus it is mostly being adopted in the fabrication of optical film and semiconductor. Operationally, a target is placed on the cathode electrode so that it can be ionized into plasma by the glow discharging between the cathode electrode and the anode electrode, and then the sputtering target resulting from the glow discharging is enabled to deposit upon a workpiece subjecting to a bias voltage.

However, since the sputtering material is primarily composed of neutral atoms and atom clouds, the said magnetron sputtering coating is disadvantageous in its low the ionization ratio that it is generally lower than 5% and thus the adhesion of a film resulting from the magnetron sputtering coating is poor. Moreover, since the working area of the said magnetron sputtering coating is usually very narrow so that the workpiece can only be placed in front of the target of about 5˜10 cm distance, the said magnetron sputtering coating is insufficient for coating large-sized workpieces.

Although there are prior-art methods capable of enhancing the ionization of the neutral atoms in the sputtering material by the use of an additional ion source, such methods can only provide little improvement but it is operating at a cost of stringent operation condition. In addition, there is another prior-art method capable of enhancing its ionization by the use of an unbalanced magnetic field as those used in unbalanced magnetron sputtering, but its ionization ratio can only reach 10% to 20%, not to mention that when its magnetic fields are unbalanced above target surface, the resulting electron beams will damage the surface of the workpiece.

Please refer to FIG. 1, which shows a voltage-ampere curve relating to plasma coating technology. In FIG. 1, the working areas for the arc plasma coating and the magnetron sputtering coating are clearly and distinctively identified. For plasma technology, the current size is generally in direction proportion to the ionization of plasma, i.e. the larger the current is, the larger the ionization will be result and the better the adhesion of its resulting film will have.

As shown in FIG. 1, the current (A) in the working area relating to the arc plasma coating is larger than the others so that the film formed thereby will have better adhesion. However, from the description hereinbefore, the surface roughness of the workpiece is deteriorated by the deposition of microparticles which is to cause its coating quality to decrease. In addition, as the arc plasma coating is operated in a vacuum environment, where a plasma is obtained between anode and cathode with low voltage (V), the power (P) of such low voltage (V) high current (A) is comparatively small as P=V×A.

On the other hand, the current (A) in the working area relating to the magnetron sputtering coating is comparatively smaller so that the adhesion of the film formed thereby is poor since the smaller current is going to cause lower ionization. Thus, it is intended to increase current in the magnetron sputtering coating. However, from the voltage-ampere curve shown in FIG. 1, the increasing of target voltage supplied by a high-power apparatus initiate a rapid increasing target current that enters a working area of high-power plasma. In such high-power plasma area, despite that the increasing of current will cause the ionization of plasma to increase as well, its power is going to increase multiplicatively by the simultaneous increasing in voltage and ampere and thus the power supply, target and workpiece are all going to be damaged or even melted since they are not designed to withstand such high power.

The high power pulse magnetron sputtering (HPPMS) is a vacuum coating technique developed at Year 1999, which is a type of magnetron sputtering whose working area is corresponding to the high-power plasma area shown in FIG. 1. The pulse peak of the HPPMS is about 100 times of the said magnetron sputtering and is in a ranged between 1000˜3000 W/cm². However, as its operating time is defined in between 100 to 150 microseconds, its average power is about the same as those conventional magnetron sputtering.

Nevertheless, there are more to be learned about the characteristics of the HPPMS and it is currently only be applied in surface cleaning process as there are still bottlenecks when it comes to the application in coating.

### SUMMARY OF THE INVENTION

In view of the disadvantages of prior art, the object of the present invention is to provide a magnetron sputtering apparatus capable of achieving a high quality coating with good adhesion and high uniformity.

Another object of the invention is to provide a surface treatment apparatus capable of accelerating the surface processing efficiency of a workpiece.

To achieve the above objects, the present invention provides a magnetron sputtering apparatus, adapted for coating a workpiece. The magnetron sputtering apparatus includes a vacuum chamber, a holder, a magnetron plasma source and a high-power pulse power supply set, wherein the magnetron plasma source includes a base, a magnetron controller and a target. A reactive gas is inputted into the vacuum chamber, and the holder supporting the workpiece is disposed inside the vacuum chamber. The magnetron plasma source is disposed opposite to the workpiece, wherein the magnetron controller is disposed in the base, and the target is disposed on the base. The high-power pulse power supply set is coupled to the vacuum chamber, the magnetron plasma source and the holder for feeding a high voltage pulse power to the magnetron plasma source so as to enable the target to react with the reactive gas and thus generate plasma to coat a film on the surface of the workpiece.

To achieve the above objects, the present invention provides a surface treatment apparatus, adapted for performing a surface processing operation upon a workpiece, which includes a vacuum chamber, a holder and a high-power pulse power supply set, wherein the holder supporting the workpiece is disposed inside the vacuum chamber and a reactive gas is inputted into the vacuum chamber. The high-power pulse power supply set is coupled to the vacuum chamber and the holder for feeding a high voltage pulse power to the holder to enable the workpiece to react with the reactive gas and thus generate plasma to coat a film on the surface of the workpiece.

In an exemplary embodiment of the invention, the duty ratio of a high-power pulse originated from the high voltage pulse power is less than 10%.

In an exemplary embodiment of the invention, the said high-power pulse power supply set further includes a high-power pulse power supply and a voltage divider; wherein the high-power pulse power supply is coupled to the vacuum chamber and the magnetron plasma source; and the voltage divider is coupled to a node sandwiched between the high-power pulse power supply and the holder. Moreover, the high-power pulse power supply set further includes a first high-power pulse power supply and a second high-power pulse power supply, in which the first high-power pulse power supply is coupled to the vacuum chamber and the magnetron plasma source; and the second high-power pulse power supply, being configured to act as a bias-voltage source, is coupled to the holder.

In an exemplary embodiment of the invention, the wave originated from the high-power pulse power supply set is a wave selected from the group consisting of: a square wave, a sine wave, a high-frequency square wave packet, a high-frequency sine wave packet, and a high-frequency sine wave packet of symmetrical positive and negative potentials. Moreover, the wave originated from the high-power pulse power supply set can be an ultra-high negative potential pulse with a bandwidth ranged between 5 ns to 1 μs and the voltage of such ultra-high negative potential pulse is smaller than −1 KV.

In an exemplary embodiment of the invention, the magnetron sputtering apparatus further comprises a vacuum pump, which can be a pump selected from the group consisting of: a mechanical pump, a booster pump, a diffusion pump, and a turbomolecular pump.

In an exemplary embodiment of the invention, the holder can be a metal clamp; the workpiece can be an object selected from the group consisting of: a metal, an alloy, a semiconductor, and a non-conductor; and the target can be an object selected from the group consisting of: a metal, an alloy, and a semiconductor.

In an exemplary embodiment of the invention, the target is used for coating a film on a surface of the workpiece while the film can be a pure metal film, a compound film and a transparent film. In addition, the said pure metal film can be made of a metal selected from titanium, chromium, gold, silver, zinc, tin, magnesium and the combination thereof; and the said compound film can be made of a material selected from TiN, TiCN, CrN, CrCN, TiAlN, TiAl, Si₃N₄, TiAlCN and the combination thereof; and the transparent film can be made of a material selected from TiO₂, SiO₂, ITO and the combination thereof.

To sum up, the magnetron sputtering apparatus of the invention has the merits of the conventional arc plasma coating and magnetron sputtering coating while overcoming their shortcomings. In addition, by the surface treatment apparatus of the invention, treatment process is faster than that process using a conventional power supply.

Further scope of applicability of the present application will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention and wherein:

FIG. 1 shows a voltage-ampere curve relating to plasma coating technology.

FIG. 2 is a schematic diagram showing a magnetron sputtering apparatus according to an exemplary embodiment of the invention.

FIG. 3 is a schematic diagram showing a high-power pulse power supply set according to an exemplary embodiment of the invention.

FIG. 4A and FIG. 4B are respectively a sectional view and a three-dimensional sectional side view of a magnetron plasma source according to another exemplary embodiment of the invention.

FIG. 5A and FIG. 5B show various high voltage pulse powers used in the magnetron sputtering apparatus of the invention.

FIG. 6 is a graph of experiment data describing a magnetron sputtering apparatus according to an exemplary embodiment of the invention.

FIG. 7 shows a surface treatment apparatus according to an exemplary embodiment of the invention.

### DESCRIPTION OF THE EXEMPLARY EMBODIMENTS

For your esteemed members of reviewing committee to further understand and recognize the fulfilled functions and structural characteristics of the invention, several exemplary embodiments cooperating with detailed description are presented as the follows.

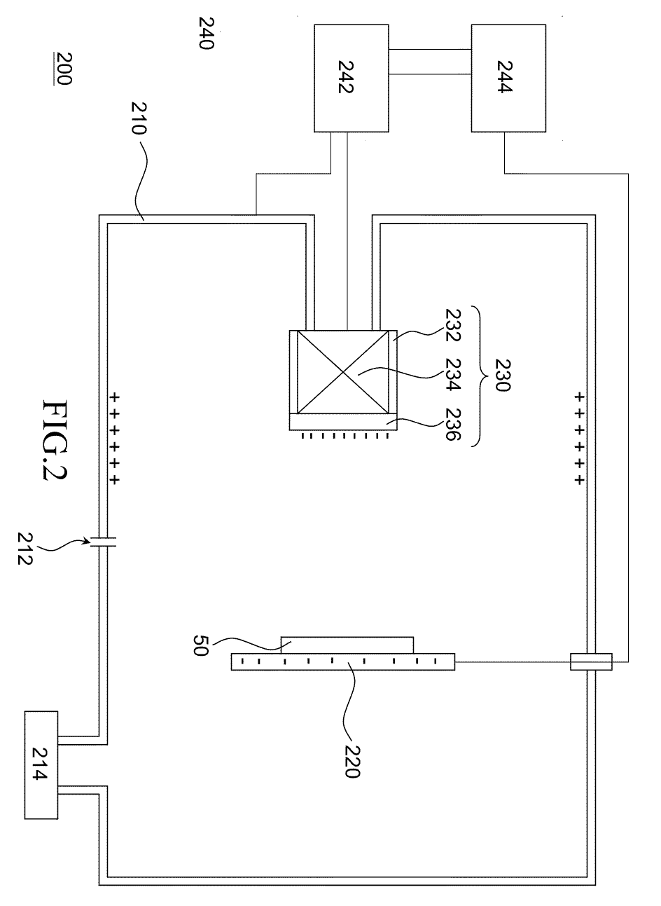

Please refer to FIG. 2, which is a schematic diagram showing a magnetron sputtering apparatus according to an exemplary embodiment of the invention. In FIG. 2, the magnetron sputtering, apparatus 200 adapted for coating a film on a workpiece 50, includes a vacuum chamber 210, a holder 220, a magnetron plasma source 230 and a high-power pulse power supply set 240, in which the holder 220 and the magnetron plasma source 230 are correspondingly disposed inside the vacuum chamber 210 at two opposite positions, and the high-power pulse power supply set 240 is coupled to the vacuum chamber 210, the magnetron plasma source 230 and the holder 220.

In addition, the magnetron plasma source further comprises a base 232, a magnetron controller 234 and a target 236, in which both the magnetron controller 234 and the target 236 are disposed on the base 232. Moreover, the workpiece 50 is placed on the holder 220 at a position corresponding to the target 236; and there is a reactive gas provided to the magnetron sputtering apparatus 200 that is fed into the vacuum chamber 210 for enabling a chemical reaction with target material. When the high-power pulse power supply set 240 is activated to input a high voltage pulse power to the magnetron plasma source 220, it will cause the target 236 to react with the reactive gas and thus generate a plasma to coat a film on a surface of the workpiece 50.

In detail, the high-power pulse power supply set 240 is activated for subjecting the holder 220 and the magnetron plasma source to a negative voltage while subjecting the vacuum chamber 210 to a positive voltage. The minute when the high-power pulse power supply set 240 is activated to input a high voltage pulse power to the magnetron plasma source 220, there are electrons being released from the surface of the target 236 and those electrons are driven to move toward the vacuum chamber wall 210 while being enabled to move in a spiral manner by the magnetron controller 234 for increasing their chances of colliding with the reactive gas. By colliding with electron, the reactive gas will be ionized to being a positive ion which will then hit the target 236 and thus cause the atom of target 236 to sputter and ionize. Those conductive assemblies of charged particles including the electrons, the position ions and the ionized target are generally referred as plasmas that are attracted by the holder 220 and thus moved toward the workpiece 50, and finally cause a film to be formed on the surface of the workpiece 50.

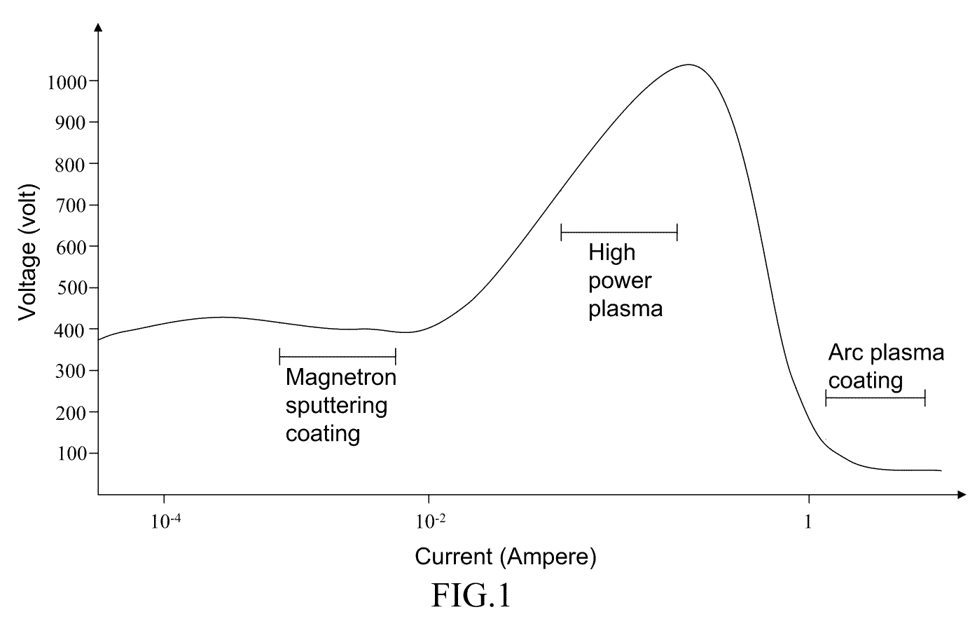

As shown in FIG. 1, the magnetron sputtering apparatus of the invention is operating in the high-power plasma area at the moment when it is charged by a high-voltage power so that its degree of ionization of plasma can reach more than 70% and thus the adhesion of a film resulting from the said magnetron sputtering coating is greatly improved. In addition, since the collision of the ions on the targets 236 is considered to be the collision performed between atom-scaled particles that it is not the “explosion” happened in those arc discharging, there will be no micron-sized or submicron-sized particles generated therefrom so that a very uniform film can be resulted from the said magnetron sputtering coating with good coating quality.

It is noted that at the instant when the magnetron sputtering apparatus is charge by the high-voltage pulse, the resulting high voltage and high current at the instant is going to subject the magnetron sputtering apparatus in a high power condition at the moment. However, since the duty ratio of the high voltage pulse power is usually less than 10%, the magnetron sputtering apparatus of the invention is operating in the average working power the same as those conventional magnetron sputtering coating devices so that it will not cause any damage to the target 236 and the workpiece 50.

Generally, the duty ratio of the high-power pulse is a value of on time divided by period time whereas the period time is the sum of the on time and off time, i.e.

Duty ratio=on time/period time; or

Duty ratio=on time/(on time+off time);

For instance, when the duty ratio of the high-power pulse is 5% and assuming the instant power density achieves 1000 W/Cm², its average power density can drop to 50 W/Cm².

From the perspective of Microphysics, at impulse time when the magnetron sputtering apparatus is charge by the high-voltage pulse, a high density plasma will be generated from the magnetron plasma source 230 and emit toward the workpiece 50 for forming a film thereon, while the temperature of the target 236 or the workpiece 50 is raised instantly to near its melting point due to the high power of the high-voltage/high-current condition. Thereafter, as soon as the power is cut off so that there are zero voltage and zero current, i.e. zero power, the temperatures of the target 236 and the workpiece 50 will drop rapidly and the same time that the plasma from the magnetron plasma source 230 that is not forming a film on the workpiece 50 will dissipate by self-coupling. Hence, before applying another high-voltage pulse on the magnetron sputtering apparatus of the invention, the temperatures of the target 236 and the workpiece 50 can maintain to their normal working temperatures for preparing the same for the next high-voltage pulse.

In detail, the voltage of the high-power pulse is larger than the voltage required for igniting a discharge between the cathode electrode and the anode electrode, so that when a target is placed on the cathode electrode for enabling the same to be ionized into plasma by the glow discharging, the higher the voltage is, the higher a discharging current will be result. At the beginning of the discharging, the pulse current at the moment of discharging can be adjusted according to the pulse duration. However, when the pulse current at the moment of discharging is saturated, the increasing of the pulse duration will no cause such pulse current to increase. It is noted that a discharging current that is overly low represents that the sputtering of the target is low, but correspondingly, it represent a high ionization ratio in gaseous material, so that a low discharging current often cause impure film. In the coating of certain compound film such as TiO, the working function of the dielectric layer TiOₓ of its target surface is low that electron can be released easily from the target by low surface voltage. However, on the other hand, the saturation value of the discharging current is very high that it usually exceeds the load of the power supply while overloading the dielectric layer of the target and thus causing arc discharging. Therefore, it is common to control its discharging current by the control of pulse duration. As the power of a pulse can be adjusted by the control of pulse frequency, in addition to proper pulse duration, an optimal condition can be achieved for subjecting the target 236 and the workpiece 50 at the status below their threshold values of temperature and arc discharging. Thereby, the ionization of the target 236 by glow discharging is maximized which will result an optimal coating quality.

Please refer to FIG. 2, which is a schematic diagram showing a magnetron sputtering apparatus according to an exemplary embodiment of the invention. The characteristic of the magnetron sputtering apparatus of the invention is its high-power pulse power supply set 240 as it is capable of supporting an instant high power load. The high-power pulse power supply set 240 is coupled to the magnetron plasma source 220 and the holder 230 simultaneously. In this embodiment, the high-power pulse power supply set 240 includes a first high-power pulse power supply 242 and a second high-power pulse power supply 244, in which the first high-power pulse power supply 242 is coupled to the vacuum chamber 210 and the magnetron plasma source 220, while the second high-power pulse power supply 244, being configured to act in synchronization with the first high-power pulse power supply 242, is coupled to the holder 230. Thereby, both the first and the second high-power pulse power supplies 242, 244 are capable of operating normally at the moment when a high-voltage power is fed to the magnetron sputtering apparatus so that plasma can be generated and emit toward the workpiece 50 smoothly for forming a film thereon.

However, if the second high-power pulse power supply 244 is a common poser supply, it is going to shut down automatically at the instant when the high-voltage power is fed to the magnetron sputtering apparatus since it is unable to support such high power load. Thus, the holder 220 will not be situated as negative potential and thus the plasma will not be drown to emit toward the workpiece 50 the minute when it is generated, but instead it will vanish after the pulse.

In another word, the high-power pulse power supply set 240 is used for exciting electrons from the target 236 for forming plasma while enabling the electrons shooting into the workpiece 50 from the plasma to move back to the high-power pulse power supply set 240, and thus forming a circuit cycle. Therefore, if there is any component in the cycle fails to function normally or is shutting down automatically, the consequence is that plasma can not be generated and emit toward the workpiece 50 smoothly for forming a film thereon which is the key issue that the magnetron sputtering apparatus of the invention trying to avoid.

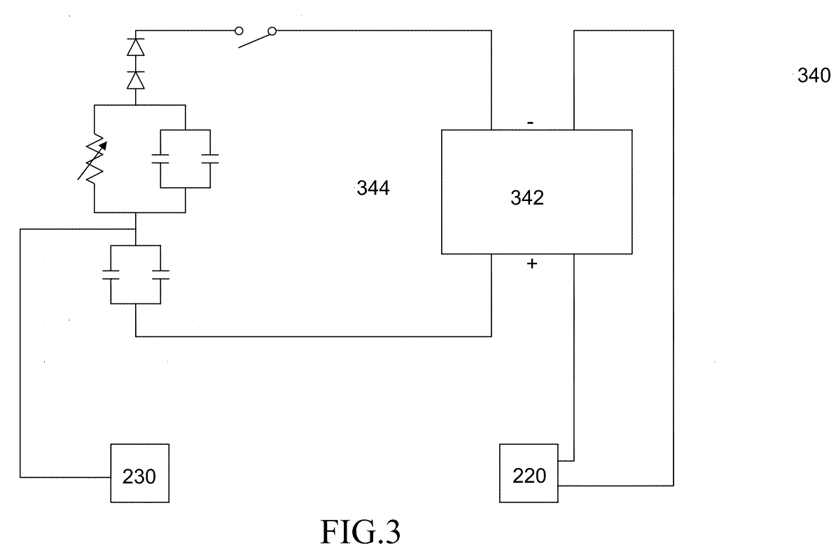

Although the high-power pulse power supply set 240 shown in FIG. 2 is composed of the first high-power pulse power supply 242 and the second high-power pulse power supply 244, but it is not limited thereby. Please refer to FIG. 3, which is a schematic diagram showing a high-power pulse power supply set according to another exemplary embodiment of the invention. For clarity, only a portion of the magnetron sputtering apparatus including the high-power pulse power supply set 340 is shown in FIG. 3, in which the high-power pulse power supply set 340 is connected to the magnetron plasma source 220 and thus further connected to the target 236 while also connecting to the holder 220 and thus further connecting to the workpiece 50. The high-power pulse power supply set 340 is comprised of a high-power pulse power supply 342 and a voltage divider 344, in which the high-power pulse power supply 342 is coupled to the magnetron plasma source 220 for forming an electric circuit; and the voltage divider 344 is capable of operating as a power supply for the holder through the high-power pulse power supply 342.

Thereby, through the voltage divider 344, another electric circuit for the high-power pulse power supply 342 is constructed by which the electrons shooting into the workpiece 50 from the plasma can be directed to move back to the high-power pulse power supply set 340 through the voltage divider 344. Thus, by replacing the said second high-power pulse power supply 244 by the simple-structured voltage divider 344, the manufacturing cost of the magnetron sputtering apparatus of the invention is reduced. Moreover, although the voltage divider 344 of FIG. 3 is composed of a plurality of capacitors and a plurality of variable resistors, it is not limited thereby.

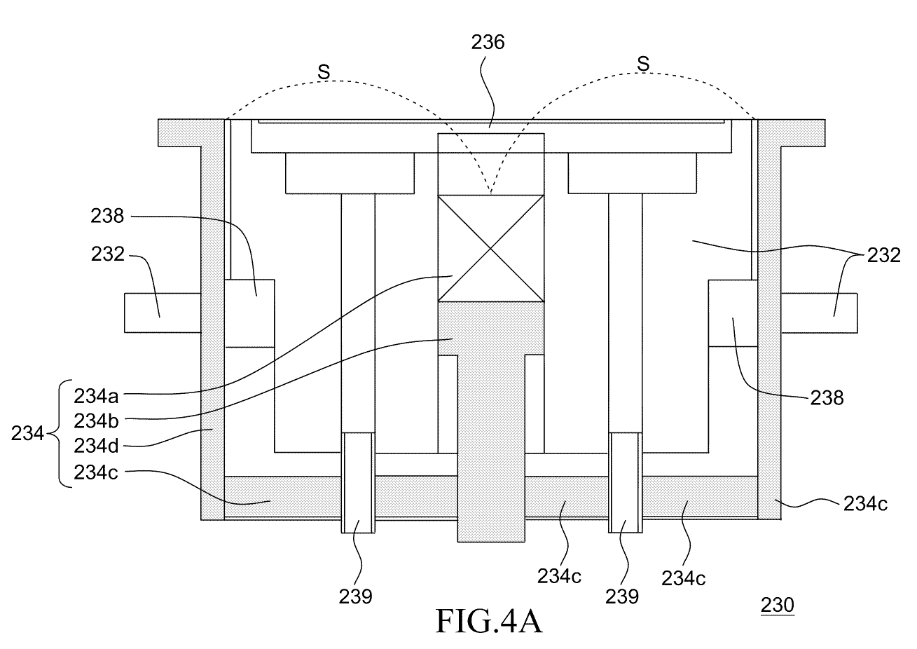

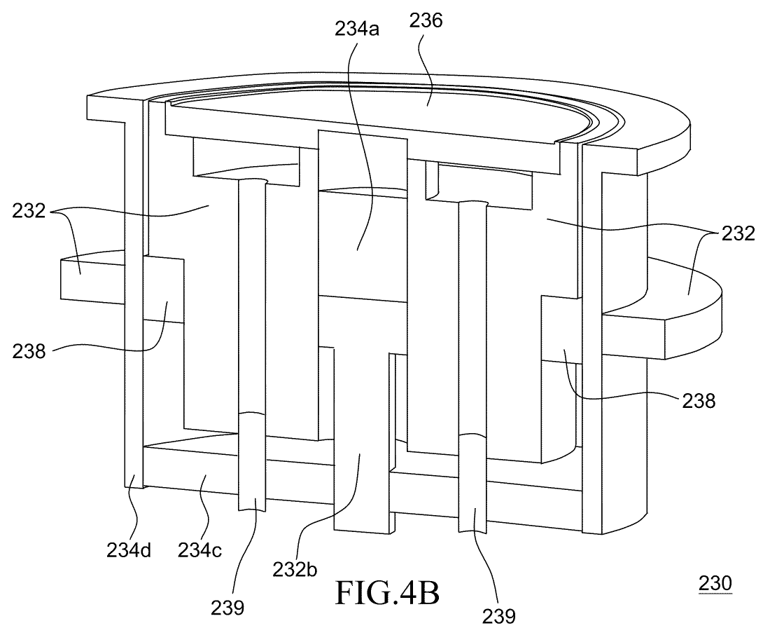

Please refer to FIG. 4A and FIG. 4B, which are respectively a sectional view and a three-dimensional sectional side view of a magnetron plasma source according to another exemplary embodiment of the invention. The magnetron plasma source 230 used in the embodiments shown in FIG. 2, FIG. 4A and FIG. 4B is comprised of a base 232, a magnetron controller 234 and a target 236, in which the base 232 is used for supporting the target 236; and the magnetron controller 234 is capable of forming a magnetic field of semi-circular loop. In detail, the magnetron controller 234 comprises a central magnet 234a and three conducting magnets 234b, 234c, 234d. by the semi-circular shaped structure of the central magnet 234a and three conducting magnets 234b, 234c, 234d, the magnetic field lines S will travel pass the top of the target 236. Thereby, when the target 236 is excited by a potential difference and emits electrons, the excited electrons will be affected by the magnetic field lines S in a manner that they will be guided to travel in a spiral path and thus their chances of colliding with the reactive gas are increased.

Moreover, the cathode electrode of the high-power pulse power supply set 240 is either being connected directly to the target 236 of the magnetron controller 230, or is first being connected to the base 232 of the magnetron controller 230 while the base 232 is connected to the target 236. In this embodiment, the anode electrode of the high-power pulse power supply set 240 is connected directly to the vacuum chamber 210 to form an electric circuit. It is noted that, instead of connecting to the vacuum chamber 210, the anode electrode can be coupled to the base 232 of the magnetron controller 230, as those shown in other embodiments, However, when it is connected to the base 232, it is required to configured insulators on the magnetron controller 230 for separating its cathode electrode from its anode electrode. In addition, it is preferred to have a water cooler 239 installed in the magnetron controller 230 for accelerating the cooling of the target 236.

In the embodiment shown in FIG. 2, the magnetron sputtering apparatus 200 further comprises a inlet 212 and a vacuum pump 214, in which the inlet 214 is an opening formed on the outer wall of the vacuum chamber 210 to be used for intaking the reactive gas; and the vacuum pump is used for vacuuming the vacuum chamber 210. In addition, the reactive gas can be argon (Ar).

In the embodiment shown in FIG. 2, the cathode electrode of the high-power pulse power supply set 240 is connected directly to the target 236 of the magnetron controller 230 and its anode electrode is connected to the vacuum chamber 210, whereas the vacuum chamber 210 is vacuumed to a vacuum degree of less than 10⁻⁵ torr. When the degree of vacuum is less than 10⁻⁵ torr, the vacuum chamber 210 will be charged with the reactive gas, i.e. argon, for raising the vacuum to about 10⁻³ torr from the inlet 212, and then a high-voltage pulse power is fed to the magnetron plasma source 230 for activating the same.

In the effective magnetic field relating to the target, there are a massive amount of electrons circling therein and colliding with the argon for ionizing the same to generate argon ions. The argon ions will hit on the target 236 of negative potential during the lasting of a pulse duration for enabling the target 236 to sputter atoms. Thereby, if the pulse duration is long enough, there will be hundreds or even thousands of amperes being caused between the cathode electrode and the anode electrode. For those conventional direct current or pulse power, they all come with some kinds of protection device that can be shut off when an instant large current is detected. The high-power pulse power supply set 240 used in the present invention is designed to withstand an instant output of thousands or even tens of thousands of amperes, and its pulse duration is designed to be adjustable.

When a target 236 made of pure metal is sputtering in a condition that its saturated pulse current per square centimeters is smaller than 3 amperes, the feasible adjusting range of the pulse duration can be very larger, which can be ranged from tens of micro-seconds to tens of thousands of micro-seconds, only if the average powers of the target 236 and the workpiece 50 are maintained within a tolerable range. In addition, when gases, such as N₂, CH₄, O₂, are charged for coating reaction dielectric film, the surface of the metal target is easily toxicated and thus arc discharging will be resulted. Therefore, it is preferred to shorten the pulse duration to an extend that it is ranged between several micro-seconds and several tens of micro-seconds while reducing the pulse current of the target 236 to less than three amperes per square centimeters, by that abnormal arc-discharging can be eliminated and thus the coating quality is increased. Moreover, when a semiconductor targeting is used for sputtering, the coating is performed in a manner similar to the coating of said reaction dielectric film, but with smaller pulse current.

It is emphasized that when a high-voltage pulse is fed to the magnetron sputtering apparatus of the invention, a discharging of an instant large current will be generated between its cathode electrode and anode electrode and the same time that a large amount of atoms will be sputtered out of the target 236 that are to be deposited on the workpiece 50 subjecting to a high-power bias voltage source. Since the ion density of the plasma generated from the magnetron plasma source 220 is high, which is ranged between from 70% to 100%, the film being deposited on the workpiece 50 can be very delicate and formed with good adhesion. Thus, the magnetron sputtering apparatus of the invention has the advantages of those conventional magnetron sputtering coating and arc plasma coating, but are freed from their shortcomings. In addition, since the duty ratio of the high voltage pulse power is usually less than 10%, the magnetron sputtering apparatus of the invention is operating in the average working power the same as those conventional magnetron sputtering coating devices so that it will not cause any damage to the target 236 and the workpiece 50.

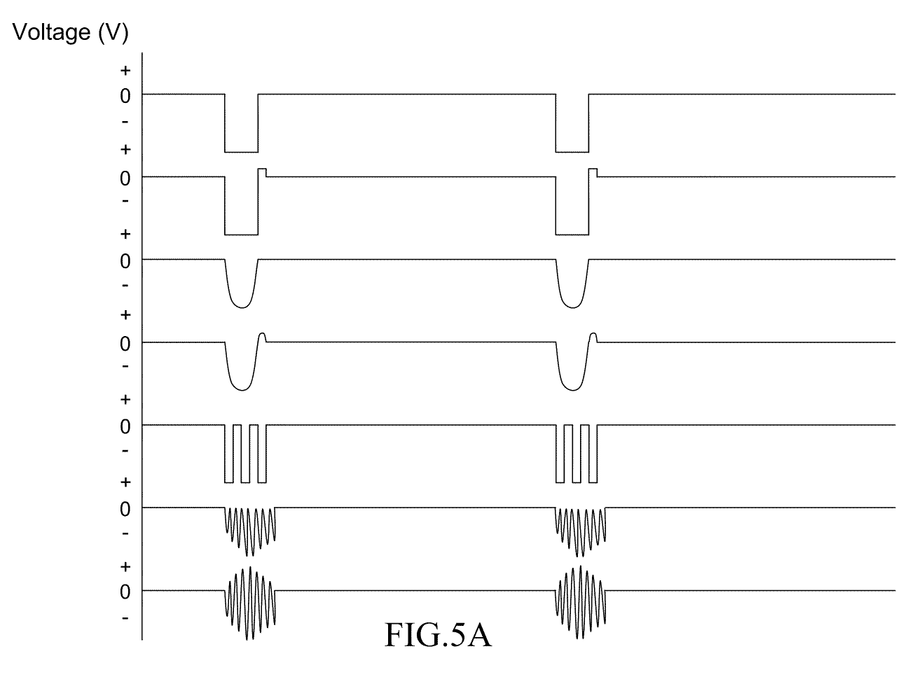

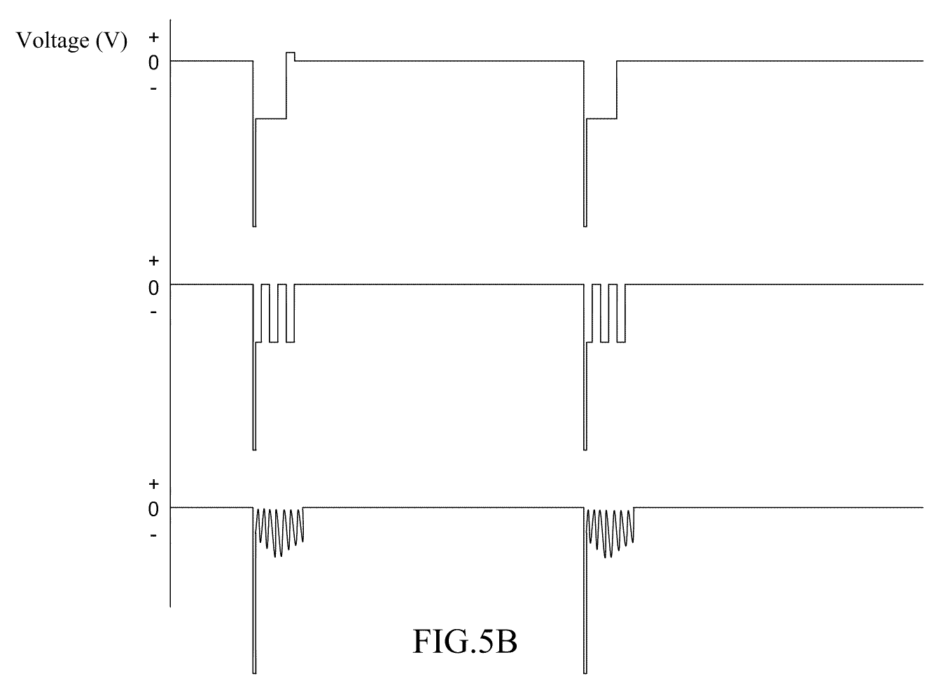

Please refer to FIG. 5A and FIG. 5B, which show various high voltage pulse powers used in the magnetron sputtering apparatus of the invention. It is noted that the waveform of the present invention is not limited to a specific wave, that the wave originated from the high-power pulse power supply set at the instant when a pulse is generated is a wave selected from the group consisting of: a square wave, a sine wave, a high-frequency square wave packet, a high-frequency sine wave packet, and a high-frequency sine wave packet of symmetrical positive and negative potentials, as those shown in FIG. 5A. Generally, for the square wave or sine wave of the same pulse frequency, their average sputtering rates are higher than those from corresponding wave packets, however, when it come to ionization ratio, the wave packets are higher since the use of such high-frequency wave packets can reduce the time required for accelerating electrons and reverse accelerating of the same and thus increasing the colliding between particles so that the ionization ratio is increased.

In this invention, the high-voltage pulse power output a negative voltage to be used for activating magnetron sputtering, and the positive voltage pulse is used for neutralize the over charges on target surface to avoid abnormal arc discharge. It is noted that those said waves shown in FIG. 5A might not be able to activate discharging when the coating is perform in certain atmosphere pressure, so that an ultra-high negative potential short pulse E, whose bandwidth ranged between 5 ns to 1 μs, and the voltage of such ultra-high negative potential pulse is more than −1 KV, is used in addition to those said waves for assisting to ignite glow discharge. Moreover, the duty ratio of the high voltage pulse power for activating the magnetron sputtering is less than 10%.

It is noted that the vacuum pump 214 used in the magnetron sputtering apparatus of the invention is not limited to a specific pump. Generally, the degree of vacuum of the invention is dependent upon the actual coating environment that its working air pressure can be ranged between atmosphere pressure to 10⁻⁶ torr vacuum. For coating under a pressure between atmosphere pressure to 10⁻² torr, the vacuum pump 214 can be an assembly of a mechanical pump and a booster pump. However, for coating under 10⁻² torr vacuum, the vacuum pump 214 can be an assembly of a mechanical pump and a diffusion pump, or an assembly of a mechanical pump and a turbomolecular pump. In addition, the holder 220 can be a metal clamp for clamping the workpiece 50, nevertheless, neither it is not limited thereby, nor the way the workpiece 50 being secured by the holder 220 is not limited by the clamping manner. Moreover, the workpiece 50 is an object selected from the group consisting of: a metal, an alloy, a semiconductor, and a non-conductor. When the workpiece 50 is made of a non-conductor, it can still exhibit a capability of excellent coating than that of conventional methods.

Generally, there are three types of film capable of being coated on the workpiece 50 by the magnetron sputtering apparatus of the invention, which are pure metal film, compound film and transparent film. The said pure metal film can be made of a metal selected from titanium (Ti), chromium (Cr), gold, silver, zinc, tin, magnesium and the combination thereof; and the said compound film can be made of a material selected from TiN, TiCN, CrN, CrCN, TiAlN, TiAl, Si₃N₄, TiAlCN and the combination thereof; and the transparent film can be made of a material selected from TiO₂, SiO₂, ITO and the combination thereof. Correspondingly, the target 236 can be made of a material selected from the group consisting of: metal, ally and semiconductor, however, it is not limited thereby.

It is noted that the structure of the magnetron plasma source 230 is not restricted to be the one shown in FIG. 4A and FIG. 4B. For instance, the target 230 of the magnetron plasma source 230 can be a panel or a column, and so on; and consequently the magnetron plasma source 230 can be structured like a rotating column or a reciprocating column at a condition that it is designed for target against pollution and is capable of performing a coating operation on a larger workpiece 50 separated from the target 236 by a comparatively longer distance. To be more specific, as the ionization ratio of the plasma generated by the magnetron sputtering apparatus of the invention can reach more than 70% and the plasma can be drawn to move in a relative fast speed by an anode electrode, the workpiece 50 can be disposed at a distance away from the target 236 that is conceivably larger than those conventional coating apparatuses and still can achieve a perfect coating. In addition, the amount of magnetron plasma source 230 is not restricted to be the same as the one shown in FIG. 4A and FIG. 4B, so that there can be a plurality of magnetron plasma sources 230 in the magnetron sputtering apparatus of the invention configured with only one high-power power supply.

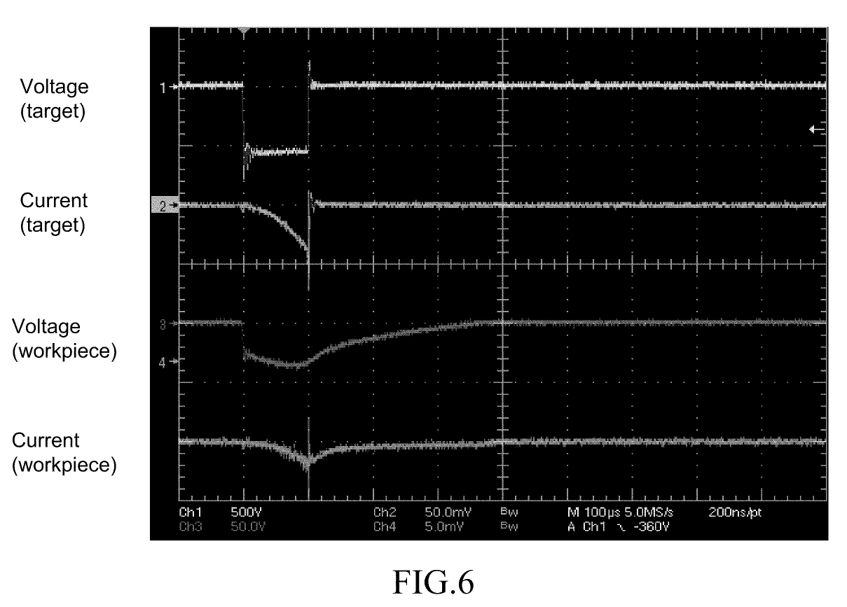

Please refer to FIG. 6, which is a graph of experiment data describing a magnetron sputtering apparatus according to an exemplary embodiment of the invention. The experiment data shown in FIG. 6 is extracted directly from a monitor, in which the first channel Ch1 and the second channel Ch2 represents respectively the voltage and the current of the target, and the third channel Ch3 and the fourth channel Ch4 represents respectively the voltage and current of the workpiece. In FIG. 6, when the pulse voltage of the target 236 in a coating process is −550V and its highest current can reaches 50 A, the bias voltage of the workpiece can reach 40V while its highest current can reach 2.5 A. In addition, the pulse width of bias voltage transient of the workpiece 50 is three times wider than the target voltage pulse and the residue plasma after the target voltage pulse can still be absorbed by the biased workpiece 50.

The following embodiment describes an actual experiment for magnetron sputtering coating a TiN film by the use of a high-power pulse. The coating starts by vacuuming the vacuum chamber 210 to 1×10⁻⁵ torr vacuum. Then the vacuum chamber 210 is introduced with 260 sccm argon gas up to a pressure of 3.7×10⁻³ torr while connecting the workpiece 50 and the magnetron plasma source 230 to a same high-power pulse power supply. After the surface of the workpiece 50 is cleaned, the high-power pulse power supply is set to issue a high-voltage pulse of −650V in an manner that its on time is 100 μs and off time is 1900 μs with frequency of 500 Hz. Thereby, at the instant of ignition, there will blue titanium plasma being generated in a space between the target 236 and the workpiece 50 whereas the pulse current of the target 236 is 300 A while its average current and average voltage are 7 A and 5 KW. The same time that the pulse bias of the workpiece 50 acts in synchronization with the pulse voltage of the target 236 whose voltage is −650V. Thus, there is a flow of ions bombarding the surface of the workpiece 50 for about 5 minutes.

Then, for coating a pure titanium film on the workpiece 50, an adjustment is performed for changing the on time to 20 μs and the off time to 1980 μs with frequency of 500 Hz while maintaining the other process parameters. Thereafter, the vacuum chamber 210 is introduced a nitrogen gas of 70 sccm up to that of 4.1×10⁻³ torr which will result the plasma to appear a light orange color. The coating process will last for about an hour.

After the coating process is completed, the workpiece 50 coated with a golden TiN film is removed from the magnetron sputtering apparatus for evaluating its characteristics. When the workpiece 50 is disposed 5 cm, 10 cm, 15 cm away from the target 236, its average deposition rates per hour are respectively 1 μm, 0.5 μm and 0.3 μm. In addition, no matter how far the workpiece 50 is disposed away from the target 236, the resulting film adhesion is more than 100 N.

The following embodiment describes an actual experiment for coating a SiO₂ film on glass, silicon wafer and PET sheet by the use of a high-power pulse magnetron sputtering. In this experiment, a disc-like target 236 of 30 cm² working area is used whereas the target 236 is made of silicon of 99.999% purity. There are two sets of workpieces 50, each including a glass, a silicon wafer and a PET sheet, being placed respectively at 14 cm and 23 cm in front of the target 236. It is noted that each of those workpieces 50 is fixed secured by the holder 220 and is connected to a 350 KHz pulse-bias power supply.

The coating starts by vacuuming the vacuum chamber 210 to 1×10⁻⁵ torr vacuum. Then the vacuum chamber 210 is introduced with 130 sccm argon gas and 7 sccm nitrogen for pressure up to 1×10⁻² torr. The high-power pulse power supply is set to issue a high-voltage pulse of −1000V in an manner that its on time is 10 μs and off time is 1000 μs. Thereby, at the instant of discharge ignition, there will be white plasma being generated in a space between the target 236 and the workpiece 50 whereas the peak pulse current of the target 236 is 23 A while the peak from those not supplied by high-power pulse power supply is only 2 A. The same time that the average voltage and average for depositing SiO₂ are 370 W and 0.37 A. The pulse bias of the workpiece 50 is −50V with 350 KHz frequency and the deposition time is about an hour.

After measuring the optical characteristic of the resulting film, it is noted that its density and transparency are all better than those resulting from the conventional magnetron sputtering and the thickness of the resulting SiO₂ film can reach 2 μm while neither will it peel from the glass, the silicon and the PET sheet, nor the PET sheet is deformed by overheating. For those workpieces 50 disposed 14 cm away from the target 236, its deposition rate can reach 1 μm per hour. In addition, the cross section of the resulting film is very smooth even it is observed by SEM and there is not even a pillar-like structure can be find in the film. Thus, it is obviously that the ionization ratio of such silicon plasma is high which can result a very delicate SiO₂ film.

Despite the previous descriptions all uses plasma coating for illustrating the concept of the invention, the present invention is not restricted to plasma coating. Even without a magnet, it is note that the high-power pulse magnetron sputtering apparatus of the invention can also be efficiently used in surface treatment, which is to be illustrate in the following embodiments.

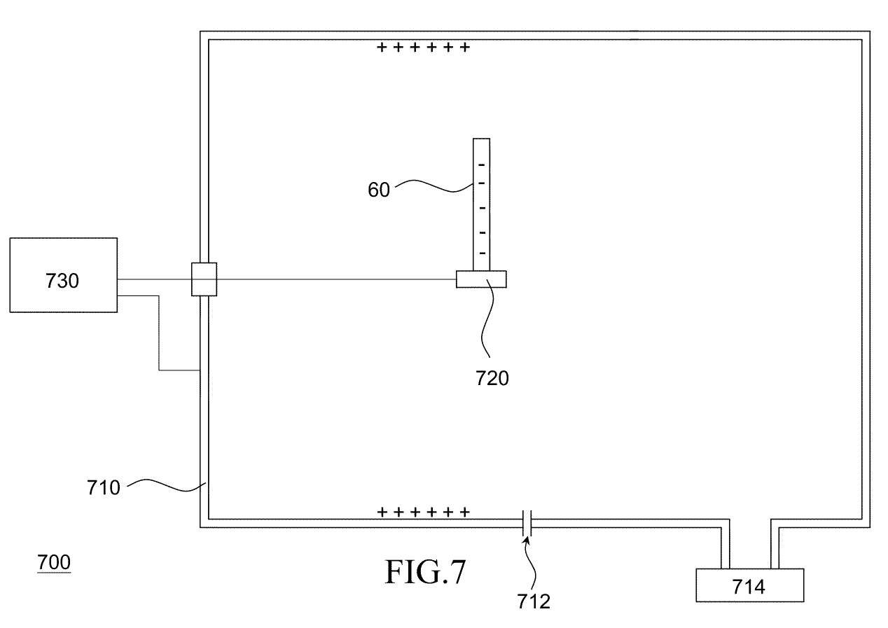

Please refer to FIG. 7, which shows a surface treatment apparatus according to an exemplary embodiment of the invention. In FIG. 7, the surface treatment apparatus 700 for performing a surface treatment operation, comprises: a vacuum chamber 710, a holder 720 and a high-power pulse power supply 730, in which the holder 720 is disposed inside the vacuum chamber 710 for supporting a workpiece 60; and the high-power pulse power supply 730 is coupled to the vacuum chamber 710 and the holder 720.

In addition, there is a reactive gas provided to the vacuum chamber 710 for enabling a reaction. When the high-power pulse power supply 730 is activated to input a high voltage pulse power to the holder 720, it will excite plasma at a position near the surface of the workpiece 60 while the excited plasma will emit toward the workpiece 60 for perform the surface treatment operation thereon. As the formation of such plasma is similar to those mentioned in the said description, it is not describe further herein.

In this embodiment, the reactive gas is nitrogen which is used for nitriding heat treatment for improve the hardness of the workpiece 60. However, the type of surface treatment operation capable of being performed by the surface treatment apparatus 700 of the invention is not restricted to the said hardness improvement. Similar to the above description, the surface treatment apparatus 700 further comprises an inlet 712 and a vacuum pump 714, in which the inlet 712 is an opening formed on the outer wall of the vacuum chamber 710 to be used for intaking the reactive gas; and the vacuum pump 714 is used for vacuuming the vacuum chamber 710.

The following embodiment describes an actual experiment for performing a plasma nitriding heat treatment on a metal workpiece for an hour by the use of a high-power pulse power supply. The treatment starts by vacuuming the vacuum chamber 710 to 1×10⁻⁵ torr vacuum. Then the vacuum chamber 710 is introduced with 2100 sccm hydrogen and 700 sccm nitrogen that total pressure near 2 torr. The cathode electrode of the high-power pulse power supply 730 is coupled to the workpiece 60 and thus further connected to the holder 720 while connecting the anode electrode to the vacuum chamber 710. It is noted that the workpiece 60 can be a SS304 steel bar of 1 inch diameter and a SACM645 steel bar of 1 inch diameter.

The high-power pulse power supply 730 is set to issue a high-voltage pulse of −1000V in an manner that its on time is 200 μs and off time is 1000 μs. Thereby, at the instant of discharge ingnition, there will be a pink nitrogen-hydrogen plasma being generated neat the workpiece 60 whereas the peak pulse current of the workpiece 60 is 10 A and the same time that the average voltage and average are 1500W and 1.5 A and the treatment time is about an hour.

After the surface treatment operation is completed, the workpiece 60 is removed from the surface treatment apparatus for evaluating its mechanical characteristics. It is noted that both the surface hardness of the SS304 steel bar and the SACM steel bar are improved respectively from 200 HV and 300 HV to 830 HV and 973 HV, which is equivalent to those being processed by conventional nitriding using a direct-current power supply for 10 hours.

To sum up, the said magnetron sputtering apparatus as well as the surface treatment apparatus have the following advantages:
(1) Since at the instant when the high-voltage pulse power is inputted, the strong plasma being generated in located inside the high-power plasma area of FIG. 1, the ionization ratio of the plasma can reach 70% which will cause the resulting film to have good adhesion.
(2) Since the discharge mode of plasma working in the present invention is abnormal glow discharge, there will be less micron-sized or submicron-sized particles being generated and thus a very uniform film can be resulted from the apparatuses of the invention with good coating quality.
(3) Comparing with those conventional surface treatment apparatuses, the surface treatment apparatus of the invention is capable of generating plasma of high ionization so that the surface treatment process can be accelerated for rapidly improving the surface hardness of the workpiece.

With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

What is claimed is:

1. A magnetron sputtering apparatus, adapted for coating a workpiece, comprising:
a vacuum chamber, provided for a reactive gas to be fed therein;
a holder, disposed inside the vacuum chamber for supporting the workpiece;
a magnetron plasma source, disposed inside the chamber at a position corresponding to the workpiece, further comprising:
a base;
a magnetron controller, disposed on the base; and
a target, disposed on the base;
and
a high-power pulse power supply set, coupled to the vacuum chamber, the magnetron plasma source and the holder for feeding a high voltage pulse power to the magnetron plasma source so as to enable a discharge between the target surface and chamber wall fed thought a reactive gas and thus generate a plasma to coat a film on a surface of the workpiece.

2. The magnetron sputtering apparatus of claim 1, wherein the duty ratio of the high voltage pulse power is usually in a region of 0.1%˜10%. For fast deposition or appropriate temperature of special coating requirement duty ratio can be adjusted to any value, even near 100%.

3. The magnetron sputtering apparatus of claim 1, wherein the high-power pulse power supply set further comprises:
a high-power pulse power supply, coupled to the vacuum chamber and the magnetron plasma source; and
a voltage divider, coupled to a node sandwiched between the high-power pulse power supply and the holder. It means that one high-power pulse power supply in coating system can simultaneously offer an electric power to multi-target and holder by aid of a voltage divider.

4. The magnetron sputtering apparatus of claim 1, wherein the high-power pulse power supply set further comprises:
a first high-power pulse power supply, coupled to the vacuum chamber and the magnetron plasma source; and
a second high-power pulse power supply, being a bias-voltage supply coupled to the vacuum chamber and the holder.

5. The magnetron sputtering apparatus of claim 1, wherein the high voltage wave originated from the high-power pulse power supply set is a wave selected from the group consisting of: a square wave, a sine wave, a high-frequency square wave packet, a high-frequency sine wave packet, and a high-frequency sine wave packet of symmetrical positive and negative potentials.

6. The magnetron sputtering apparatus of claim 5, wherein the high voltage wave originated from the high-power pulse power supply set is consist of a different pulse which contain a leading pulse with ultra-high negative potential to easily ignite a discharge between cathode target and anode chamber wall in special coating process.

7. The magnetron sputtering apparatus of claim 6, wherein the ultra-high negative potential pulse has a bandwidth ranged between 5 ns to 1 μs, and the voltage of such ultra-high negative potential pulse is near −3 KV. In general condition of plasma coating, voltage of high-power pulse in the present invention is smaller than −1 KV.

8. The magnetron sputtering apparatus of claim 1, wherein the magnetron sputtering apparatus further comprises:
a vacuum pump, being a pump selected from the group consisting of: a mechanical pump, a booster pump, a diffusion pump, and a turbomolecular pump.

9. The magnetron sputtering apparatus of claim 1, wherein the holder is a metal clamp.

10. The magnetron sputtering apparatus of claim 1, wherein the workpiece is an object selected from the group consisting of: a metal, an alloy, a semiconductor, and a non-conductor.

11. The magnetron sputtering apparatus of claim 1, wherein the target is an object selected from the group consisting of: a metal, an alloy, and a semiconductor.

12. The magnetron sputtering apparatus of claim 1, wherein the target is capable of coating a pure metal film on the surface of the workpiece while the pure metal film is made of a metal selected from titanium, chromium, gold, silver, zinc, tin, magnesium and the combination thereof.

13. The magnetron sputtering apparatus of claim 11, wherein the target is capable of coating a compound film on the surface of the workpiece while the compound film is made of a material selected from TiN, TiCN, CrN, CrCN, TiAlN, TiAl, Si₃N₄, TiAlCN and the combination thereof.

14. The magnetron sputtering apparatus of claim 11, wherein the target is used for coating a transparent film on the surface of the workpiece while the transparent film is made of a material selected from TiO₂, SiO₂, ITO and the combination thereof.

15. A surface treatment apparatus, comprising:
a vacuum chamber, provided for a reactive gas to be fed therein;
a holder, disposed inside the vacuum chamber for supporting the workpiece; and
a high-power pulse power supply set, coupled to the vacuum chamber and the holder for feeding a high voltage pulse power to the magnetron plasma source so as to enable the target to react with the reactive gas and thus generate a plasma to coat a film on a surface of the workpiece.

16. The surface treatment apparatus of claim 15, wherein the duty ratio of the high voltage pulse power is less than 10%.

17. The surface treatment apparatus of claim 15, wherein the wave originated from the high-power pulse power supply set is a wave selected from the group consisting of: a square wave, a sine wave, a high-frequency square wave packet, a high-frequency sine wave packet, and a high-frequency sine wave packet of symmetrical positive and negative potentials.

18. The surface treatment apparatus of claim 17, wherein the wave originated from the high-power pulse power supply set is an ultra-high negative potential pulse.

19. The surface treatment apparatus of claim 18, wherein the ultra-high negative potential pulse has a bandwidth ranged between 5 ns to 1 μs, and the voltage of such ultra-high negative potential pulse is smaller than −1 KV.

20. The surface treatment apparatus of claim 15, wherein the surface treatment apparatus further comprises:
a vacuum pump, being a pump selected from the group consisting of: a mechanical pump, a booster pump, a diffusion pump, and a turbomolecular pump.

21. The surface treatment apparatus of claim 15, wherein the holder is a metal clamp.

22. The surface treatment apparatus of claim 15, wherein the workpiece is an object selected from the group consisting of: a metal, an alloy, a semiconductor, and a non-conductor.
